(19) United States
(12) Patent Application Publication
(10) Pub. No.: US 2024/0364818 A1
(43) Pub. Date: Oct. 31, 2024

(54) ULTRASONIC APPARATUS

(71) Applicant: SEIKO EPSON CORPORATION, TOKYO (JP)

(72) Inventors: Masayoshi YAMADA, SHIOJIRI-SHI (JP); Hikaru IWAI, MATSUKAWA-MACHI (JP)

(21) Appl. No.: 18/643,024

(22) Filed: Apr. 23, 2024

(30) Foreign Application Priority Data
Apr. 26, 2023 (JP) 2023-072366

(51) Int. Cl. H04N 1/00; G01N 29/24

(52) U.S. Cl. CPC H04N 1/0001; G01N 29/2437

(57) ABSTRACT

An ultrasonic apparatus includes a circuit substrate on which a ground electrode is formed, an ultrasonic device that is mounted on a first surface of the circuit substrate; and a shield that is electrically connected to the ground electrode and that surrounds the ultrasonic device, wherein the circuit substrate has a through hole that penetrates between the first surface and a second surface, which is at an opposite side from the first surface, the shield has a main body section that is disposed on the first surface of the circuit substrate and that surrounds the ultrasonic device and a leg section that extends from the main body section and that passes through the through hole and protrudes from the second surface, and a protruding section is provided on a portion of the leg section that protrudes from the second surface and the protruding section protrudes, when the second surface is viewed in plan view, further outward than the through hole.

The present application is based on, and claims priority from JP Application Serial Number 2023-072366, filed Apr. 26, 2023, the disclosure of which is hereby incorporated by reference herein in its entirety.

### BACKGROUND

### 1. Technical Field

The present disclosure relates to an ultrasonic apparatus.

### 2. Related Art

JP-A-2020-25242 discloses an ultrasonic apparatus that includes a circuit substrate, a base section, an ultrasonic element, and a shield section. The base section is disposed on the circuit substrate. The ultrasonic element is disposed on the base section. The base section is interposed between the circuit substrate and the ultrasonic element. The shield section, which is an example of a shield, covers the base section and the ultrasonic element. The shield section is fixed to the circuit substrate.

JP-A-2020-25242 does not describe how the shield is secured to the circuit substrate. In a previous ultrasonic apparatus, there is room for improvement in the way the shield is secured.

### SUMMARY

An ultrasonic apparatus includes a circuit substrate on which a ground electrode, which is connected to a ground potential, is formed; an ultrasonic device that is mounted on a first surface of the circuit substrate; and a shield that is electrically connected to the ground electrode and that surrounds the ultrasonic device; wherein the circuit substrate has a through hole that penetrates between the first surface and a second surface, which is at an opposite side from the first surface, the shield has a main body section that is disposed on the first surface of the circuit substrate and that surrounds the ultrasonic device and a leg section that extends from the main body section and that passes through the through hole and protrudes from the second surface, and a protruding section is provided on a portion of the leg section that protrudes from the second surface and the protruding section protrudes, when the second surface is viewed in plan view, further outward than the through hole.

### BRIEF DESCRIPTION OF THE DRAWINGS

FIG. 1 is a perspective view showing the appearance of an image scanner.

FIG. 2 is a schematic diagram showing a schematic configuration of the image scanner.

FIG. 3 is a plan view showing the ultrasonic element substrate.

FIG. 4 is a cross-sectional view cut along line A-A in FIG. 3.

FIG. 5 is a block diagram showing a configuration of control section of the image scanner.

FIG. 6 is a perspective view showing a configuration of each of a transmission unit and a reception unit.

FIG. 7 is an exploded perspective view showing a configuration of each of the transmission unit and the reception unit.

FIG. 8 is a perspective view showing a shield of the first example.

FIG. 9 is a cross-sectional view cut along line A-A in FIG. 6.

FIG. 10 is a perspective view showing the shield of the first example.

FIG. 11 is an enlarged view of a portion B in FIG. 9.

FIG. 12 is a perspective view showing an ultrasonic unit including a shield of a second example.

FIG. 13 is a plan view showing the ultrasonic unit including the shield of the second example.

FIG. 14 is a perspective view showing a shield of a third example.

FIG. 15 is a side view showing the shield of the third example.

FIG. 16 is an exploded cross-sectional view showing the ultrasonic unit having the shield of the third example.

### DESCRIPTION OF EMBODIMENTS

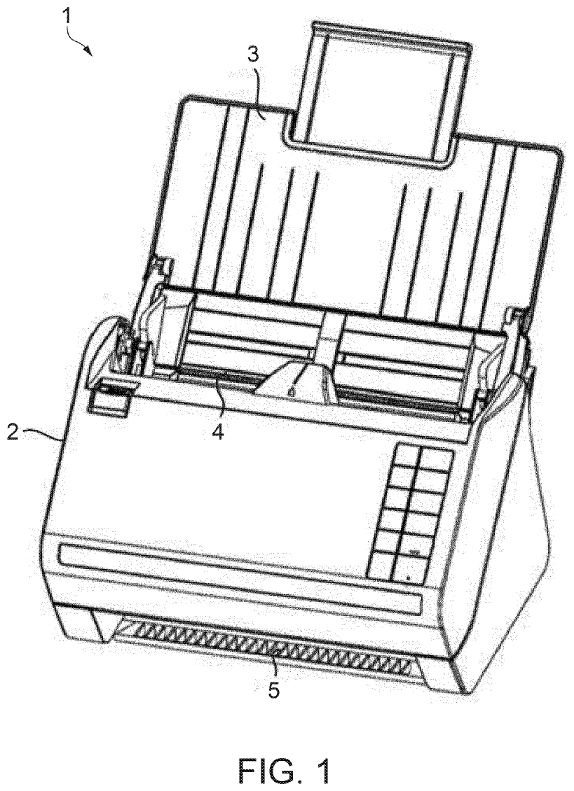

An embodiment will be described using an image scanner as an example. As shown in FIG. 1, the image scanner 1 includes an outer case 2 and a document support 3. The image scanner 1 is a scanning device that scans an image of a document M placed on the document support 3. The document M is an example of a medium.

The outer case 2 constitutes an outer shell of the image scanner 1. The outer case 2 is provided with a supply port 4 and a discharge port 5. The document M in a cut-sheet form is placed on the document support 3. The document support 3 is configured to have placed thereon a plurality of sheets of the document M. The document support 3 is disposed above the outer case 2. The document support 3 is provided at a position that connects to the supply port 4. The supply port 4 is an introduction port for introducing the document M placed on the document support 3 into the inside of the outer case 2. The supply port 4 is connected to the document support 3. The supply port 4 is disposed above the outer case 2. The discharge port 5 is an exit through which the document M introduced into the outer case 2 from the supply port 4 is discharged to the outside of the outer case 2. The discharge port 5 is provided below the outer case 2.

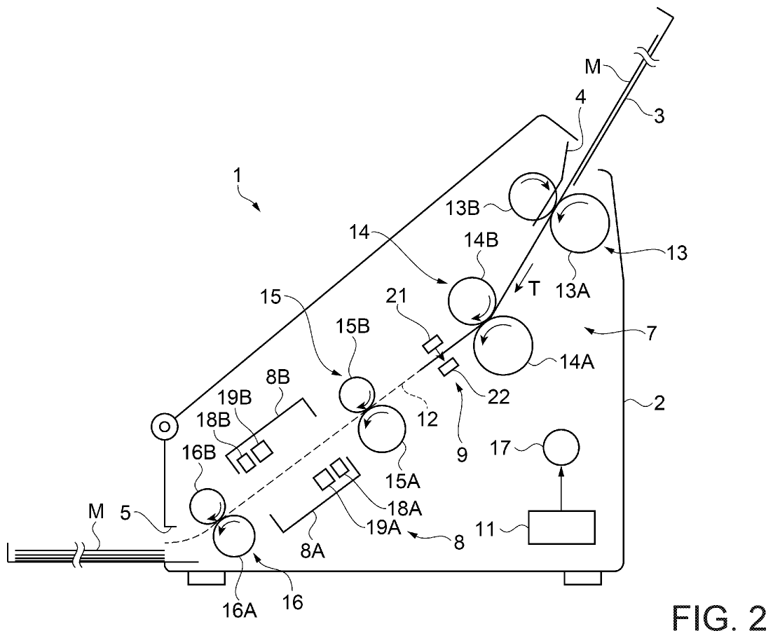

As shown in FIG. 2, the image scanner 1 includes a transport device 7, a scanning unit 8, an ultrasonic sensor 9, and a control unit 11 inside the outer case 2. The transport device 7 transports the document M that is introduced into the outer case 2 from the supply port 4, in the transport direction T toward the discharge port 5. The transport device 7 transports the document M from an upper portion of the outer case toward a lower portion of the outer case 2. The document M is not limited to paper. The document M may be formed from film, fabric, or the like. The transport device 7 transports the document M placed on the document support 3 one sheet at a time. The transport device 7 includes a transport path 12, a first transport roller pair 13, a second transport roller pair 14, a third transport roller pair 15, and a fourth transport roller pair 16.

The transport path 12 is the movement path of the document M from the supply port 4 to the discharge port 5. The document M is transported from the supply port 4 to the discharge port 5 along the transport path 12. The first transport roller pair 13, the second transport roller pair 14, the third transport roller pair 15, and the fourth transport roller pair 16 are arranged along the transport path 12. The transport path 12 corresponds to an example of a transport track. Each of the first transport roller pair 13, the second transport roller pair 14, the third transport roller pair 15, and the fourth transport roller pair 16 is an example of a transport roller.

The first transport roller pair 13 transports the document M, which is supplied to the supply port 4, along the transport path 12. When a plurality of sheets of document M are placed on the document support 3, the first transport roller pair 13 supplies the uppermost sheet of the document M of the plurality of sheets of document M into the transport path 12. The first transport roller pair 13 includes a first drive roller 13A and a first driven roller 13B. The first drive roller 13A transmits a drive force for transporting the document M. The first drive roller 13A is rotationally driven by the drive force of a transport motor 17 (to be described later). The first drive roller 13A transports the document M along the transport path 12 by being rotationally driven. The first driven roller 13B is in contact with the first drive roller 13A. The first driven roller 13B is driven to rotate when the first drive roller 13A is rotationally driven. The first driven roller 13B and the first drive roller 13A sandwich the document M therebetween and transport the document M along the transport path 12.

The second transport roller pair 14 is disposed downstream from the first transport roller pair 13 in the transport direction T. The second transport roller pair 14 transports the document M transported by the first transport roller pair 13 along the transport path 12. The second transport roller pair 14 functions as a separation mechanism that separates the document M transported by the first transport roller pair 13 into individual sheets. The second transport roller pair 14 includes a second drive roller 14A and a second driven roller 14B. The second drive roller 14A transmits a drive force for transporting the document M. The second drive roller 14A is rotationally driven by the drive force of the transport motor 17. The second drive roller 14A is rotationally driven to transport the document M along the transport path 12. The second driven roller 14B is in contact with the second drive roller 14A. The second driven roller 14B is driven to rotate when the second drive roller 14A is rotationally driven. The second driven roller 14B and the second drive roller 14A sandwich the document M and transport the document M along the transport path 12. A friction coefficient of the outer circumferential surface of the second driven roller 14B with respect to the document M is larger than a friction coefficient of the outer circumferential surface of the second drive roller 14A with respect to the document M. The document M is separated one sheet at a time by the rotation of the second transport roller pair 14.

The third transport roller pair 15 is disposed downstream of the second transport roller pair 14 in the transport direction T. The third transport roller pair 15 transports the document M transported by the second transport roller pair 14 along the transport path 12. The third transport roller pair 15 includes a third drive roller 15A and a third driven roller 15B. The third drive roller 15A transmits a drive force for transporting the document M. The third drive roller 15A is rotationally driven by the drive force of the transport motor 17. The third drive roller 15A is rotationally driven to transport the document M along the transport path 12. The third driven roller 15B is in contact with the third drive roller 15A. The third driven roller 15B is driven to rotate when the third drive roller 15A is rotationally driven. The third driven roller 15B and the third drive roller 15A sandwich the document M and transport the document M along the transport path 12.

The fourth transport roller pair 16 is disposed downstream of the third transport roller pair 15 in the transport direction T. The fourth transport roller pair 16 transports the document M transported by the third transport roller pair 15 along the transport path 12. The fourth transport roller pair 16 transports the document M toward the discharge port 5. The fourth transport roller pair 16 includes a fourth drive roller 16A and a fourth driven roller 16B. The fourth drive roller 16A transmits a drive force for transporting the document M. The fourth drive roller 16A is rotationally driven by the drive force of the transport motor 17. The fourth drive roller 16A is rotationally driven to transport the document M along the transport path 12. The fourth driven roller 16B is in contact with the fourth drive roller 16A. The fourth driven roller 16B is driven to rotate when the fourth drive roller 16A is rotationally driven. The fourth driven roller 16B and the fourth drive roller 16A sandwich the document M and transport the document M along the transport path 12.

The scanning unit 8 scans the document M transported along the transport path 12. The scanning unit 8 is disposed along the transport path 12. In this embodiment, the scanning unit 8 is disposed between the third transport roller pair 15 and the fourth transport roller pair 16. In other words, the scanning unit 8 is located upstream from the fourth transport roller pair 16 in the transport path 12. The scanning unit 8 is located downstream from the third transport roller pair 15 in the transport path 12. The scanning unit 8 includes a first scanner 8A and a second scanner 8B. The first scanner 8A and the second scanner 8B are located on opposite sides of the transport path 12.

The first scanner 8A scans a first surface of the document M transported along the transport path 12. The first scanner 8A scans the first surface of the document M and generates first scanning data. The first scanner 8A includes a first light source 18A and a first image sensor 19A. The first light source 18A irradiates light onto the first surface of the document M. The first light source 18A is disposed at a position facing the first surface of the document M. The first light source 18A irradiates the light along the document width direction, which is orthogonal to the transport direction T of the document M.

The first image sensor 19A receives the light reflected from the first surface of the document M. The first image sensor 19A scans the first surface of the document M by receiving the light. The first image sensor 19A is configured to extend in the document width direction. The first scanner 8A irradiates the light to the first surface of the document M from the first light source 18A, and receives the light reflected from the first surface of the document M by the first image sensor 19A. The first image sensor 19A scans the first surface of the document M by receiving the light at the first image sensor 19A.

The second scanner 8B scans a second surface of the document M transported along the transport path 12. The second surface of the document M is a back surface of the first surface of the document M. The second scanner 8B scans the second surface of the document M and generates second scanning data. The second scanner 8B includes a second light source 18B and a second image sensor 19B. The second light source 18B irradiates light onto the second surface of the document M. The second light source 18B is disposed at position facing the second surface of the document M. The second light source 18B irradiates the light along the document width direction, which is orthogonal to the transport direction T of the document M. The configuration of the second light source 18B may be the same as or different from that of the first light source 18A. The configuration of the second light source 18B is desirably the same as that of the first light source 18A.

The second image sensor 19B receives the light reflected from the second surface of the document M. The second image sensor 19B scans the second surface of the document M by receiving the light. The second image sensor 19B is configured to extend in the document width direction. The configuration of the second image sensor 19B may be the same as or different from the configuration of the first image sensor 19A. The configuration of the second image sensor 19B is desirably the same as that of the first image sensor 19A. The second scanner 8B irradiates the light onto the second surface of the document M from the second light source 18B, and receives light reflected from the second surface of the document M by the second image sensor 19B. The second image sensor 19B scans the second surface of the document M by receiving the light at the second image sensor 19B.

The ultrasonic sensor 9 detects overlapped feeding of the document M transported along the transport path 12. In this embodiment, the ultrasonic sensor 9 is disposed between the second transport roller pair 14 and the third transport roller pair 15. In other words, the ultrasonic sensor 9 is located upstream from the third transport roller pair 15 in the transport path 12. The ultrasonic sensor 9 is located downstream from the second transport roller pair 14 in the transport path 12. The ultrasonic sensor 9 is disposed along the transport path 12. The ultrasonic sensor 9 is a part of the configuration of the transport device 7. The ultrasonic sensor 9 includes a transmission unit 21 and a reception unit 22. The transmission unit 21 and the reception unit 22 are located on opposite sides of the transport path 12.

The transmission unit 21 transmits ultrasonic waves. The transmission unit 21 includes an ultrasonic transmitting element. The ultrasonic transmitting element generates ultrasonic waves. The ultrasonic waves generated by the ultrasonic transmitting element are transmitted from the transmission unit 21 toward the transport path 12. When the ultrasonic waves are transmitted while the document M is being transported to a position facing the transmission unit 21, the ultrasonic waves pass through the document M and are transmitted to the reception unit 22. When the ultrasonic waves pass through the document M, the sound pressure of the ultrasonic waves attenuates.

The reception unit 22 receives the ultrasonic waves. The reception unit 22 includes an ultrasonic reception element. The ultrasonic reception element receives the ultrasonic waves. The ultrasonic waves transmitted from the transmission unit 21 toward the transport path 12 are received by the ultrasonic reception element of the reception unit 22. The reception unit 22 receives the ultrasonic waves that are transmitted from the transmission unit 21 and that pass through the transport path 12. If the ultrasonic waves are transmitted while the document M is being transported at the position facing the transmission unit 21, the reception unit 22 receives the ultrasonic waves that passed through the document M. The reception unit 22 generates a reception signal corresponding to the sound pressure of the ultrasonic waves. The reception unit 22 sends the generated reception signal to the control unit 11.

The transmission unit 21 and the reception unit 22 have the same configuration. The configurations of the transmission unit 21 and the reception unit 22 will be described later. The ultrasonic sensor 9 includes a transmission unit 21 and a reception unit 22, but is not limited to this configuration. The transmission unit 21 may have the function of the reception unit 22. The transmission unit 21 receives the ultrasonic waves reflected from the document M. The transmission unit 21 generates a reception signal corresponding to the sound pressure of the received ultrasonic waves. The transmission unit 21 sends the generated reception signal to the control unit 11.

The control unit 11 is a controller that performs various kinds of control. The control unit 11 is, for example, a processor including a central processing unit (CPU). The control unit 11 may be composed of one or more processors. The control unit 11 may include a memory such as a random access memory (RAM) or a read only memory (ROM). The memory functions as a work area of the control unit 11. The control unit 11 functions as various functional sections by executing a control program stored in a memory (not shown).

The control unit 11 controls the transport of the document M by the transport device 7 by controlling the drive of the transport motor 17. The control unit 11 transports the document M along the transport path 12 by driving the transport motor 17. The control unit 11 controls the timing of starting the document M transport, the speed of document M transport, the stopping of document M transport, and the like. The control unit 11 controls scanning of the document M by controlling the drive of the scanning unit 8. The control unit 11 causes the scanning unit 8 to scan the document M by operating the scanning unit 8. The control unit 11 controls scanning start timing, scanning stop timing, single-sided or double-sided scanning, and the like of the scanning unit 8. The transport motor 17 generates the drive force for driving various drive rollers. The transport motor 17 transmits the generated drive force to various drive rollers via a drive transmission mechanism (not shown). The transport motor 17 rotationally drives the first drive roller 13A, the second drive roller 14A, the third drive roller 15A, and the fourth drive roller 16A.

The control unit 11 receives the reception signal output from the ultrasonic sensor 9. The control unit 11 detects overlapped feeding of the document M based on the received reception signal. The control unit 11 stops the transport of the document M when overlapped feeding is detected. The control unit 11 causes to stop the document M transport by controlling the transport device 7. Also, the control unit 11 controls the drive of the ultrasonic sensor 9. The control unit 11 controls the drive of the ultrasonic transmitting element of the transmission unit 21. The control unit 11 controls the drive of the ultrasonic reception element of the reception unit 22. The ultrasonic sensor 9 and the control unit 11 are an example of an ultrasonic apparatus. The ultrasonic sensor 9 and the control unit 11 are an example of an overlapped feeding detection device.

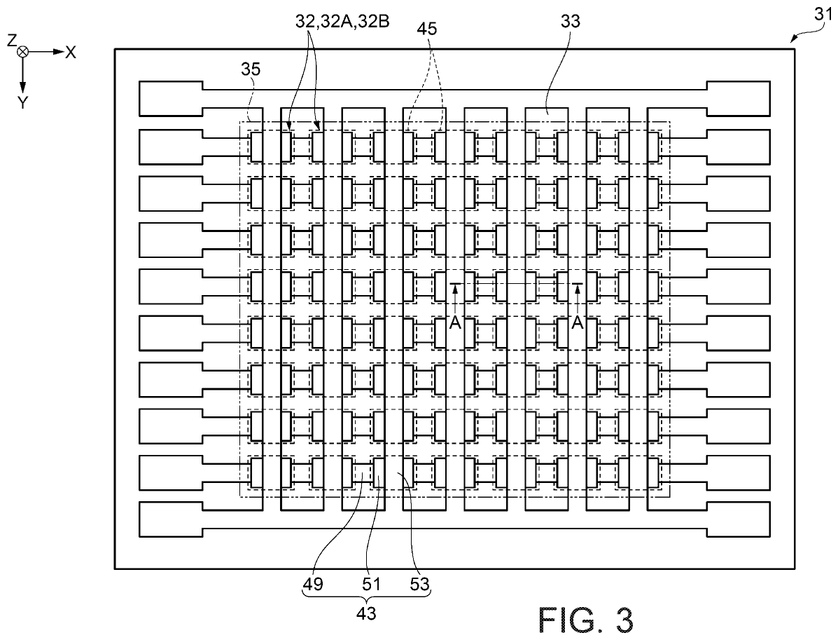

Each of the transmission unit 21 and the reception unit 22 includes an ultrasonic element substrate 31 shown in FIG. 3. The ultrasonic element substrate 31 is an example of an ultrasonic device. The ultrasonic element substrate 31 includes a plurality of ultrasonic elements 32. The ultrasonic element 32 generates ultrasonic waves or receives ultrasonic waves according to the supplied drive signal. In the ultrasonic element substrate 31 of the transmission unit 21, the ultrasonic element 32 is referred to as an ultrasonic transmitting element 32A. In the ultrasonic element substrate 31 of the reception unit 22, the ultrasonic element 32 is referred to as an ultrasonic reception element 32B. The plurality of ultrasonic elements 32 are formed on a main surface 33 of the ultrasonic element substrate 31. The main surface 33 is one of the two surfaces that have the largest area among the multiple surfaces that form the ultrasonic element substrate 31.

In a plurality of drawings including FIG. 3, an X-axis, a Y-axis, and a Z-axis are marked. The Z-axis is along a direction perpendicular to the main surface 33. The X-axis is an axis that is orthogonal to the Z-axis. The X-axis is an axis parallel to the longitudinal sides of the ultrasonic element substrate 31. The Y-axis is an axis that is orthogonal to each of the Z-axis and the X-axis. The Y-axis is an axis parallel to the shorter sides of the ultrasonic element substrate 31. Arrows are marked on the X-axis, the Y-axis, and the Z-axis, respectively. Directions indicated by the arrows are + directions. Directions opposite to the + directions are − directions. The +Z direction is a direction from the main surface 33 toward the back surface of the main surface 33. FIG. 3 is a plan view of the ultrasonic element substrate 31 in the +Z direction.

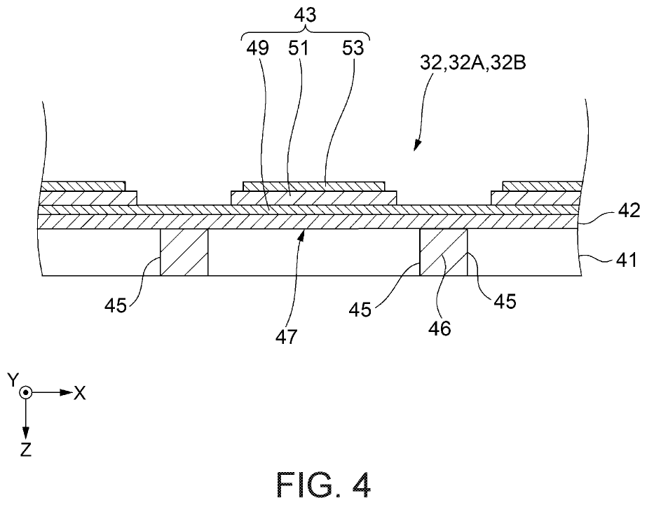

In the ultrasonic element substrate 31, the plurality of ultrasonic elements 32 constitute an element array 35. The element array 35 is an array of a plurality of ultrasonic elements 32. In the ultrasonic element substrate 31, the plurality of ultrasonic elements 32 form a matrix with an array along the X-axis as rows and an array along the Y-axis as columns. As shown in FIG. 4, which is a cross-sectional view cut along line A-A in FIG. 3, the ultrasonic element substrate 31 includes a substrate main body section 41, a vibrating plate 42, and a piezoelectric element 43. The substrate main body section 41, the vibrating plate 42, and the piezoelectric element 43 are disposed along the Z-axis. The vibrating plate 42 is disposed on the −Z direction side of the substrate main body section 41. The piezoelectric element 43 is disposed on the −Z direction side of the vibrating plate 42.

The substrate main body section 41 is made of a semiconductor substrate such as Si. A plurality of opening sections 45 are formed in the substrate main body section 41. The opening sections 45 are surrounded by partition walls 46. The plurality of opening sections 45 are formed along the X-axis and the Y-axis. The opening sections 45 pass through the substrate main body section 41. The plurality of opening sections 45 are partitioned by the partition walls 46. Since the vibrating plate 42 is provided to the −Z direction side of the substrate main body section 41, an end portion of the −Z direction side of the opening sections 45 is closed by the vibrating plate 42. The opening sections 45 open toward the +Z direction. In the ultrasonic element substrate 31, the vibrating plate 42 is exposed through the opening sections 45. The vibrating plate 42 is composed of a laminate of silicon oxide and zirconium oxide, or the like. The vibrating plate 42 is supported by the partition walls 46 of the substrate main body section 41. The +Z direction side surface of the vibrating plate 42 comprises the vibration surface 47.

One opening section 45 corresponds to one piezoelectric element 43. An opening section 45 is formed for each of the piezoelectric elements 43. The partition walls 46 are formed by forming the opening sections 45 in the substrate main body section 41. In other words, the partition walls 46 are the remaining portions of the substrate main body section 41 where the opening sections 45 are formed. A portion of the vibrating plate 42 that overlaps one opening section 45 and the piezoelectric element 43 that overlaps one opening section 45 constitute one ultrasonic element 32. In the transmission unit 21, one ultrasonic element 32 corresponds to one ultrasonic transmitting element 32A. In the transmission unit 21, the vibrating plate 42 vibrates to transmit the ultrasonic waves from the vibration surface 47. The ultrasonic transmitting element 32A converts an electrical signal into ultrasonic waves. The ultrasonic reception element 32B converts ultrasonic waves into an electrical signal. In the transmission unit 21, the ultrasonic transmitting element 32A converts the electrical signal into ultrasonic waves and transmits the ultrasonic waves. In the reception unit 22, the ultrasonic reception element 32B receive the ultrasonic waves and converts the ultrasonic waves into the electrical signal.

In the reception unit 22, one ultrasonic element 32 corresponds to one ultrasonic reception element 32B. In the reception unit 22, the vibrating plate 42 vibrates by receiving the ultrasonic waves at the vibration surface 47. An electric signal is output from the piezoelectric element 43 in response to the vibration of the vibrating plate 42. When the vibrating plate 42 vibrates by receiving the ultrasonic wave, the piezoelectric element 43 converts the vibration into an electrical signal. The plurality of piezoelectric elements 43 are provided on the −Z direction side surface of the vibrating plate 42. The piezoelectric element 43 is disposed at a position in the −Z direction side of the opening section 45. The piezoelectric element 43 includes a first electrode 49, a piezoelectric body 51, and a second electrode 53. The first electrode 49 is disposed on the −Z direction side surface of the vibrating plate 42. The first electrode 49, the piezoelectric body 51, and the second electrode 53 are stacked in this order on the −Z direction side surface of the vibrating plate 42. The piezoelectric body 51 is formed of, for example, a piezoelectric material such as lead zirconate titanate (PZT).

As shown in FIG. 3, the first electrode 49 is an electrode commonly connected to the plurality of piezoelectric elements 43 in each row of the element array 35. The second electrode 53 is a common electrode connected to the plurality of piezoelectric elements 43. In the ultrasonic transmitting elements 32A, the first electrode 49 sends an electrical signal to the piezoelectric bodies 51 of the plurality of piezoelectric elements 43. The piezoelectric body 51 expands and contracts according to the electric signal. The piezoelectric body 51 expands and contracts when a pulse wave voltage of a predetermined frequency is applied between the first electrode 49 and the second electrode 53. The expansion and contraction of the piezoelectric body 51 causes the vibration surface 47 shown in FIG. 4 to vibrate at a frequency corresponding to the opening width of the opening section 45. By this, the ultrasonic transmitting element 32A generates ultrasonic waves.

In the ultrasonic reception element 32B, the first electrode 49 receives the electric signal from the piezoelectric bodies 51 of the plurality of piezoelectric elements 43. In the ultrasonic reception element 32B, when the vibration surface 47 shown in FIG. 4 receives an ultrasonic wave, the piezoelectric body 51 expands and contracts via the vibrating plate 42. When the piezoelectric body 51 expands and contracts, the potential difference between the first electrode 49 and the second electrode 53 will change. The ultrasonic reception element 32B outputs an electric signal corresponding to the change of the potential difference. The generated electric signal is output to the control unit 11 as a reception signal.

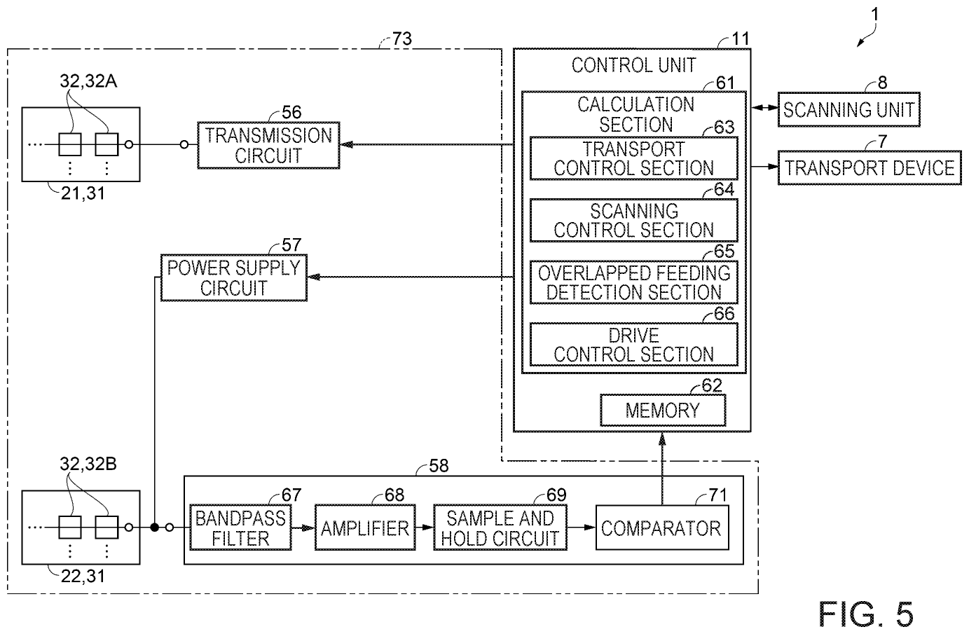

As shown in FIG. 5, the image scanner 1 includes a transmission circuit 56, a power supply circuit 57, and a reception circuit 58. The image scanner 1 may include an interface section for communicating with an external device such as a personal computer. The control unit 11 includes a calculation section 61 and a memory 62. The calculation section 61 includes a transport control section 63, a scanning control section 64, a overlapped feeding detection section 65, and a drive control section 66. The memory 62 functions as a work area of the control unit 11. The control unit 11 functions as various functional sections by executing a control program stored in the memory 62.

The control unit 11 functions as each functional section of the transport control section 63, the scanning control section 64, the overlapped feeding detection section 65, and the drive control section 66 by executing the control program stored in the memory 62. The transport control section 63 controls the drive of the transport motor 17. The transport control section 63 controls the transport device 7 by controlling the drive of the transport motor 17. The scanning control section 64 controls the scanning unit 8. The scanning control section 64 causes the scanning unit 8 to scan an image of the document M.

The transmission circuit 56 is electrically connected to the ultrasonic transmitting element 32A of the transmission unit 21. The transmission circuit 56 generates a drive signal to be applied to each of the ultrasonic transmitting elements 32A based on a command from the control unit 11. The power supply circuit 57 is electrically connected to the ultrasonic reception elements 32B of the reception unit 22. The power supply circuit 57 generates a DC voltage to be applied to the ultrasonic reception elements 32B based on a command from the control unit 11. The transmission circuit 56 and the power supply circuit 57 are each controlled by the drive control section 66 of the control unit 11. The reception circuit 58 performs various kinds of processing on the reception signal output from the ultrasonic reception element 32B of the reception unit 22, and then outputs the reception signal to the control unit 11.

The reception circuit 58 includes a bandpass filter 67, an amplifier 68, a sample and hold circuit 69, and a comparator 71. The reception signal output from the reception unit 22 is input to the bandpass filter 67. Noise components and the like are removed from the reception signal by the bandpass filter 67. The reception signal is amplified by the amplifier 68 so that the signal becomes equal to or greater than a predetermined signal intensity. Next, the reception signal is input to the sample and hold circuit 69. The sample and hold circuit 69 samples the reception signal at a predetermined frequency. The sampled reception signal is input to the comparator 71. The comparator 71 detects the reception signal having a signal intensity exceeding the predetermined determination intensity among the sampled reception signals. The comparator 71 sends the reception signal exceeding the determination intensity to the control unit 11.

The overlapped feeding detection section 65 detects the overlapped feeding state of the sheets of the document M. The reception unit 22 receives the ultrasonic waves that are transmitted from the transmission unit 21 and that pass through the document M. The reception unit 22 outputs a reception signal corresponding to the received ultrasonic waves. The overlapped feeding detection section 65 determines the state of the document M based on the reception signal input from the reception unit 22. If the voltage value of the reception signal is smaller than the determination value, the overlapped feeding detection section 65 determines that sheets of the document M are being fed in an overlapped state. When the overlapped feeding detection section 65 determines that the sheets of the document M are being fed in an overlapped state, the transport control section 63 stops transporting the document M.

The drive control section 66 instructs the transmission circuit 56 to generate a drive signal. Upon receiving the instruction to generate the drive signal, the transmission circuit 56 outputs a pulse wave voltage of a predetermined frequency as the drive signal to the transmission unit 21. In this embodiment, the driving signal output to the transmission unit 21 is a burst waveform drive signal. Driving the ultrasonic transmitting element 32A by the drive signal output from the transmission circuit 56 to the transmission unit 21 is referred to as transmission drive.

The drive control section 66 controls the power supply circuit 57. The drive control section 66 controls a drive voltage to be applied to the ultrasonic reception element 32B by controlling the power supply circuit 57. The drive control section 66 applies a DC voltage to the ultrasonic reception elements 32B or stops applying the DC voltage by controlling the power supply circuit 57. The drive control section 66 changes the voltage value of the drive voltage applied to the ultrasonic reception element 32B by controlling the power supply circuit 57. Applying the drive voltage to the ultrasonic reception element 32B by the drive control section 66 controlling the power supply circuit 57 is referred to as reception drive.

The transmission unit 21, the reception unit 22, the transmission circuit 56, the power supply circuit 57, the reception circuit 58, and the drive control section 66 are a part of the configuration of the ultrasonic apparatus 73. The drive control section 66 as a functional section is an example of a control section. The ultrasonic apparatus 73 includes the transmission unit 21, the reception unit 22, the transmission circuit 56, the power supply circuit 57, the reception circuit 58, and the drive control section 66. However, the components of the ultrasonic apparatus 73 are not limited to these, and may include other configurations. The transmission unit 21, the reception unit 22, the transmission circuit 56, the power supply circuit 57, the reception circuit 58, the drive control section 66, and the overlapped feeding detection section 65 are a part of the configuration of the overlapped feeding detection device. The overlapped feeding detection device includes the transmission unit 21, the reception unit 22, the transmission circuit 56, the power supply circuit 57, the reception circuit 58, the drive control section 66, and the overlapped feeding detection section 65. However, the components of the overlapped feeding detection device are not limited to these, and may include other configurations.

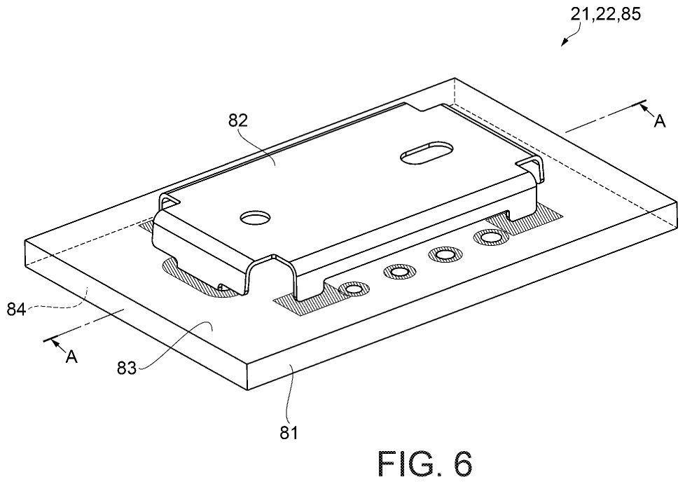

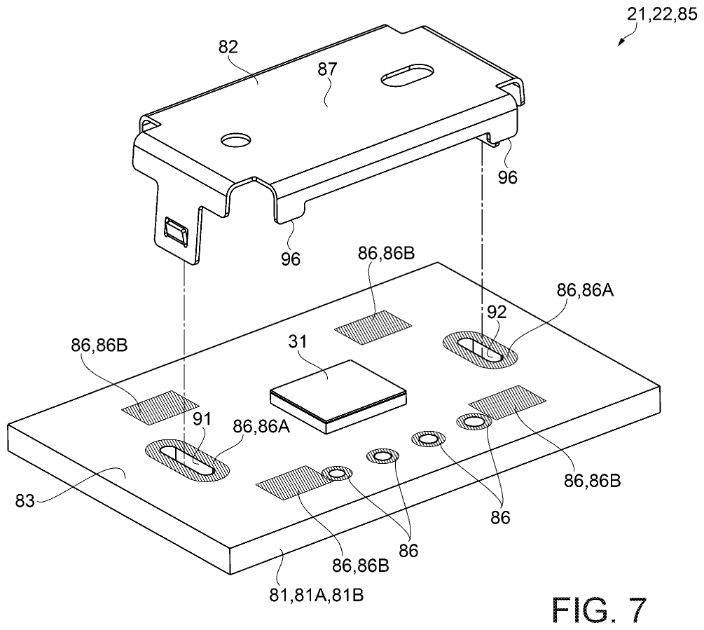

As shown in FIG. 6, each of the transmission unit 21 and the reception unit 22 includes a circuit substrate 81 and a shield 82. The circuit substrate 81 has a first surface 83 and a second surface 84. The shield 82 is disposed on the first surface 83 of the circuit substrate 81. The second surface 84 is the opposite surface from the first surface 83. The second surface 84 is a back surface of the first surface 83. As shown in FIG. 7, the ultrasonic element substrate 31 is mounted on the circuit substrate 81. The circuit substrate 81 is a general term of a substrate on which the ultrasonic element substrate 31 is mounted. Thus, it can be said that the transmission unit 21 and the reception unit 22 have the same configuration. Therefore, each of the transmission unit 21 and the reception unit 22 can be collectively referred to as an ultrasonic unit 85.

A plurality of wirings 86 are formed on the circuit substrate 81. The ultrasonic element substrate 31 mounted on the circuit substrate 81 is electrically connected to some of the plurality of wirings 86. The ultrasonic element substrate 31 of the transmission unit 21 is connected to the transmission circuit 56 shown in FIG. 5 via the wirings 86 of the circuit substrate 81. The ultrasonic element substrate 31 of the reception unit 22 is connected to the power supply circuit 57 and the reception circuit 58 shown in FIG. 5 via the wirings 86 of the circuit substrate 81. The plurality of wirings 86 include a ground electrode 86A and a ground electrode 86B. The ground electrodes 86A and 86B are connected to a metallic frame (not shown) of the image scanner 1 via the wirings 86 of the circuit substrate 81. By this, the ground electrode 86A and the ground electrode 86B are maintained at the ground potential of the chassis ground.

The circuit substrate 81 of the transmission unit 21 and the circuit substrate 81 of the reception unit 22 may be the same substrate or different substrates. The transmission circuit 56 shown in FIG. 5 may be formed on the circuit substrate 81 of the transmission unit 21. The power supply circuit 57 and the reception circuit 58 shown in FIG. 5 may be formed on the circuit substrate 81 of the reception unit 22. Note that when the circuit substrate 81 of the transmission unit 21 and of the reception unit 22 are to be distinguished between each other, the circuit substrate 81 of the transmission unit 21 is referred to as a transmission circuit substrate 81A, and the circuit substrate 81 of the reception unit 22 is referred to as a reception circuit substrate 81B. The shield 82 is formed of a conductive material, and protects the ultrasonic element substrate 31 and the wirings 86 from electromagnetic noise. In this embodiment, the shield 82 is made of metal.

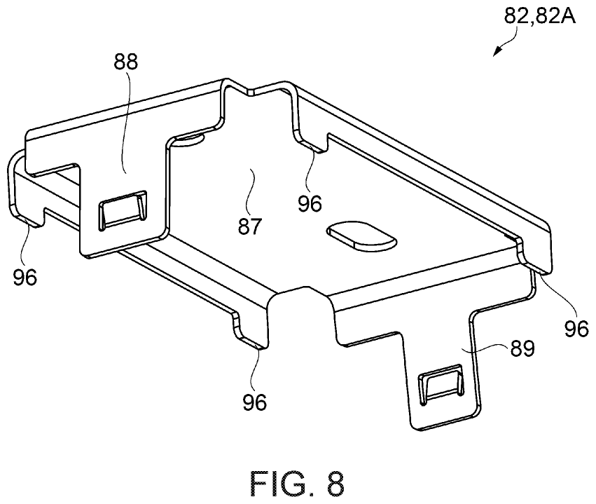

A first example of the shield 82 will be described. The first example of the shield 82 is referred to as a shield 82A. The ultrasonic unit 85 having the shield 82A is referred to as an ultrasonic unit 85A. As shown in FIG. 8, the shield 82A has a main body section 87, a first leg section 88, and a second leg section 89. The first leg section 88 and the second leg section 89 are examples of leg sections. Each of the first leg section 88 and the second leg section 89 extends from the main body section 87. As shown in FIG. 7, the main body section 87 is a portion that surrounds the ultrasonic element substrate 31 from the first surface 83 side of the circuit substrate 81. The main body section 87 is disposed on the first surface 83. Each of the first leg section 88 and the second leg section 89 extends from the main body section 87 toward the circuit substrate 81. A first through hole 91 and a second through hole 92 are formed in the circuit substrate 81. The first through hole 91 and the second through hole 92 are examples of through holes.

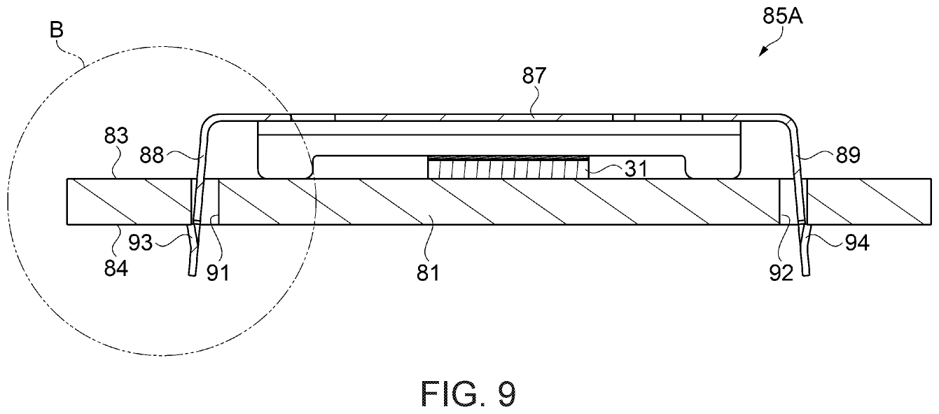

FIG. 9 is a cross-sectional view cut along line A-A in FIG. 6. As shown in FIG. 9, each of the first through hole 91 and the second through hole 92 penetrates between the first surface 83 and the second surface 84 of the circuit substrate 81. When viewing the first surface 83 in plan view, the first through hole 91 and the second through hole 92 are located on opposite sides to each other with the ultrasonic element substrate 31 interposed therebetween. Viewing the first surface 83 in a plan view means looking at the circuit substrate 81 in a state of facing the first surface 83. In other words, viewing the first surface 83 in plan view means looking at the circuit substrate 81 in a direction from the first surface 83 toward the second surface 84.

The first leg section 88 protrudes from the second surface 84 through the first through hole 91. The second leg section 89 protrudes from the second surface 84 through the second through hole 92. When viewing the first surface 83 in plan view, the first leg section 88 and the second leg section 89 are located on opposite sides of the ultrasonic element substrate 31 from each other. A first claw 93 is provided at a portion of the first leg section 88 that protrudes from the second surface 84 of the circuit substrate 81. A second claw 94 is provided at a portion of the second leg section 89 that protrudes from the second surface 84 of the circuit substrate 81.

When viewing the second surface 84 in plan view, the first claw 93 protrudes to outside of the first through hole 91. When viewing the second surface 84 in plan view, the second claw 94 protrudes further outside than is the second through hole 92. The first claw 93 and the second claw 94 are examples of protruding sections. Viewing the second surface 84 in a plan view means looking the circuit substrate 81 in a state of facing the second surface 84. In other words, viewing the second surface 84 in plan view means viewing the circuit substrate 81 in a direction from the second surface 84 toward the first surface 83. The shield 82A can be attached to the circuit substrate 81 by inserting the first leg section 88 into the first through hole 91 from the first surface 83 side and by inserting the second leg section 89 into the second through hole 92 from the first surface 83 side.

When viewing the second surface 84 in plan view, the first claw 93 of the shield 82A protrudes to outside of the first through hole 91 and the second claw 94 protrudes to outside of the second through hole 92. By this, the first claw 93 and the second claw 94 hook onto the second surface 84. Therefore, it is easy to prevent the first leg section 88 from pulling out off from the first through hole 91, and it is easy to prevent the second leg section 89 from pulling out from the second through hole 92. As a result, the shield 82A can be fixed to the circuit substrate 81. According to this structure of the shield 82A, the shield 82A can be secured to the circuit substrate 81 by the first leg section 88 and second leg section 89, which are located on opposite sides of the ultrasonic element substrate 31 from each other as viewed the first surface 83 in plan view. As a result, it is easy to stably fix the shield 82A to the circuit substrate 81.

Each of the first leg section 88 and the second leg section 89 has elasticity. The shield 82A is attached to the circuit substrate 81, in a state where the first leg section 88 and the second leg section 89 are bent inward, by inserting the first leg section 88 into the first through hole 91 and by inserting the second leg section 89 into the second through hole 92. The term “inward” means that directions in which the first leg section 88 and the second leg section 89 face each other. If the first claw 93 and the second claw 94 protrude from the second surface 84, a part of the deflection of each of the first leg section 88 and the second leg section 89 is released. Even when the first claw 93 and the second claw 94 protrude from the second surface 84, deflection remains in the first leg section 88 and the second leg section 89. Therefore, when the first claw 93 and the second claw 94 protrude from the second surface 84, the first leg section 88 and the second leg section 89 bias the circuit substrate 81 outward. The term “outward” means directions opposite to directions in which the first leg section 88 and the second leg section 89 face each other.

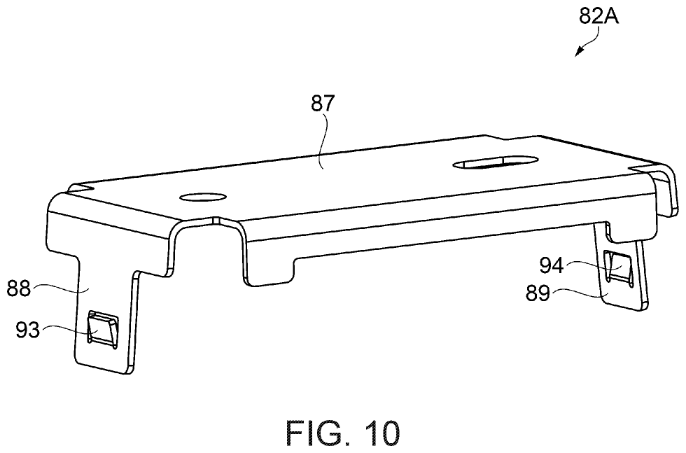

As shown in FIG. 10, the first claw 93 is formed by bending a portion of sheet metal of the first leg section 88. The second claw 94 is formed by bending a portion of sheet metal of the second leg section 89. The first claw 93 and the second claw 94 open outward from each other. In other words, the first claw 93 and the second claw 94 are bent outward from each other. However, it is also possible to adopt a configuration in which the first claw 93 and the second claw 94 are bent inward. Even in this configuration, the shield 82A can be fixed to the circuit substrate 81 if the first claw 93 protrudes to the outside of the first through hole 91 and the second claw 94 protrudes to the outside of the second through hole 92.

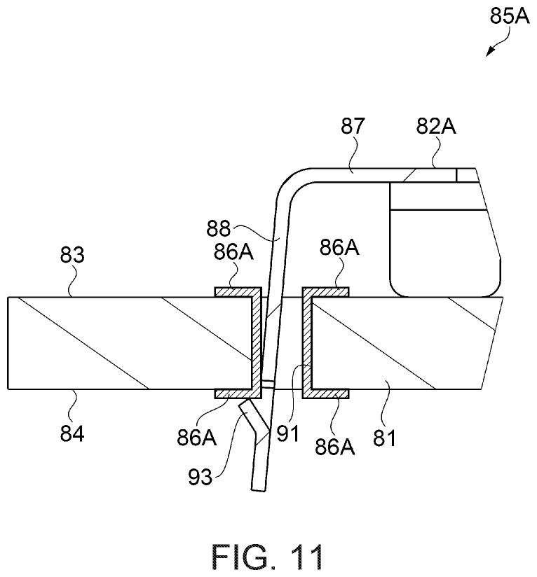

FIG. 11 is an enlarged view of a portion B in FIG. 9. As shown in FIG. 11, the ground electrode 86A formed around the first through hole 91 on the first surface 83 extends to the second surface 84 through the first through hole 91. A tip end portion of the first claw 93 contacts the ground electrode 86A extending over the second surface 84. Although not shown, the ground electrode 86A formed around the second through hole 92 on the first surface 83 also extends to the second surface 84 through the second through hole 92. A tip end portion of the second claw 94 contacts the ground electrode 86A extending over the second surface 84. Therefore, the shield 82A is maintained at the ground potential. The shield 82A can protect the ultrasonic element substrate 31 and the wirings 86 from electromagnetic noise.

As shown in FIG. 7, the ground electrodes 86B are provided on the first surface 83 of the circuit substrate 81. In this embodiment, a plurality of ground electrodes 86B are formed on the first surface 83 of the circuit substrate 81. In this embodiment, four ground electrodes 86B are formed on the first surface 83. As shown in FIG. 8, the shield 82A has a plurality of contact sections 96. Each of the plurality of contact sections 96 extends from the main body section 87. In this embodiment, the shield 82A has four contact sections 96. As shown in FIG. 7, each of the plurality of contact sections 96 extends from the main body section 87 toward the first surface 83 of the circuit substrate 81.

The ground electrodes 86B are formed at positions corresponding to the respective contact sections 96. In other words, when viewing the first surface 83 of the circuit substrate 81 in plan view, the ground electrodes 86B are located in regions overlapping the contact sections 96. Each contact section 96 is in contact with the corresponding ground electrode 86B. According to this configuration, the shield 82A can be electrically connected to the ground electrode 86B via the contact sections 96. Further, by sandwiching the circuit substrate 81 between the plurality of the contact sections 96 and the first and second claws 93 and 94, it is possible to strengthen the fixing force of the shield 82A for the circuit substrate 81.

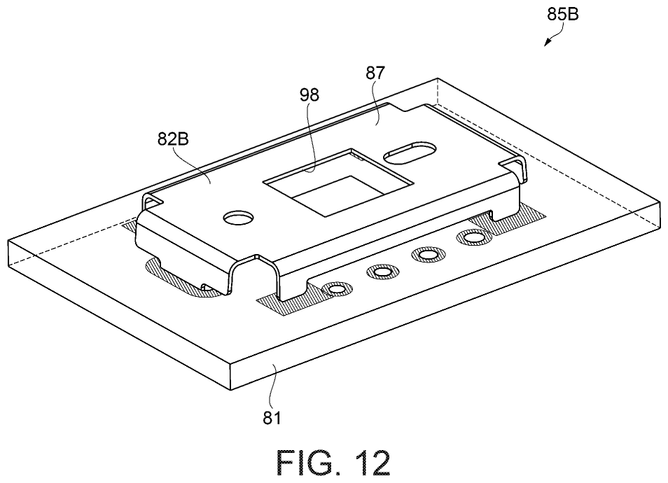

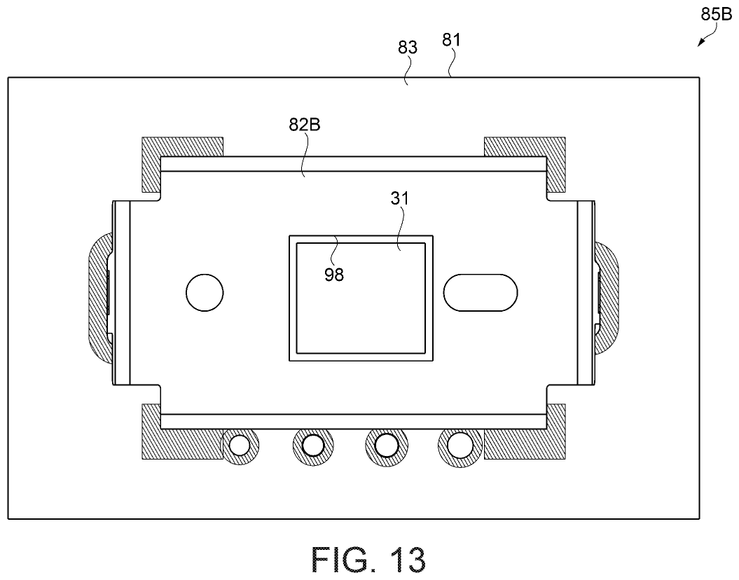

A second example of the shield 82 will be described. The second example of the shield 82 is referred to as a shield 82B. The ultrasonic unit 85 having the shield 82B is referred to as an ultrasonic unit 85B. As shown in FIG. 12, an opening 98 is formed in the shield 82B of the ultrasonic unit 85B. The opening 98 is formed in the main body section 87. The shield 82B has the same configuration as the shield 82A except that the opening 98 is formed in the main body section 87. In the following description, the same configurations of the shield 82B as those of the shield 82A are denoted by the same reference numerals as those of the shield 82A, and detailed description thereof will be omitted. As shown in FIG. 13, when viewing the first surface 83 of the circuit substrate 81 in plan view, the opening 98 is formed in a region overlapping the ultrasonic element substrate 31. Therefore, even when the opening 98 is formed in the main body section 87, the shield 82B surrounds the ultrasonic element substrate 31. According to this configuration, it is possible for the ultrasonic waves to easily pass through the opening 98.

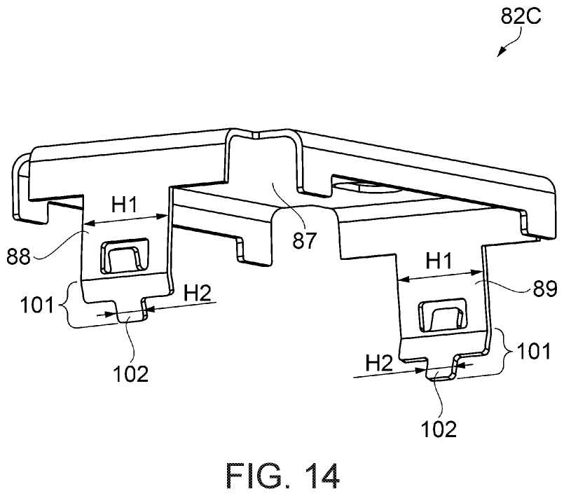

A third example of the shield 82 will be described. The third example of the shield 82 is referred to as a shield 82C. The ultrasonic unit 85 having the shield 82C is referred to as an ultrasonic unit 85C. As shown in FIG. 14, in the shield 82C, introduction portions 101 are formed in each of the first leg section 88 and the second leg section 89. The shield 82C has a configuration similar to that of the shield 82A except that the shield 82C has the introduction portions 101. In the following description, the same configurations of the shield 82C as those of the shield 82A are denoted by the same reference numerals as those of the shield 82A, and detailed description thereof will be omitted. The introduction portion 101 is formed at the distal portion of the first leg section 88, which is at the opposite side from the main body section 87 side. The introduction portion 101 is formed at a distal portion of the second leg section 89, which is at the opposite side from the main body section 87 side.

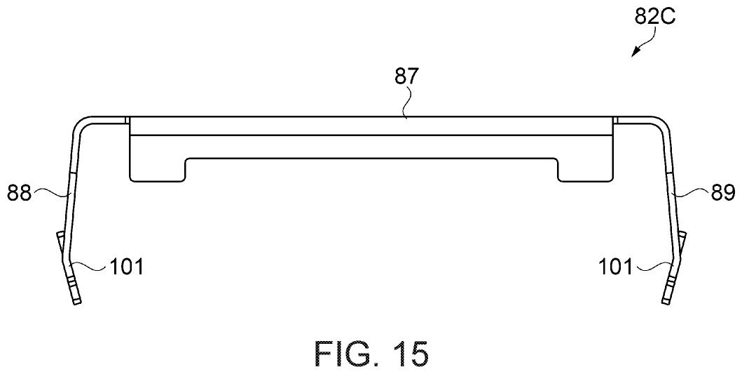

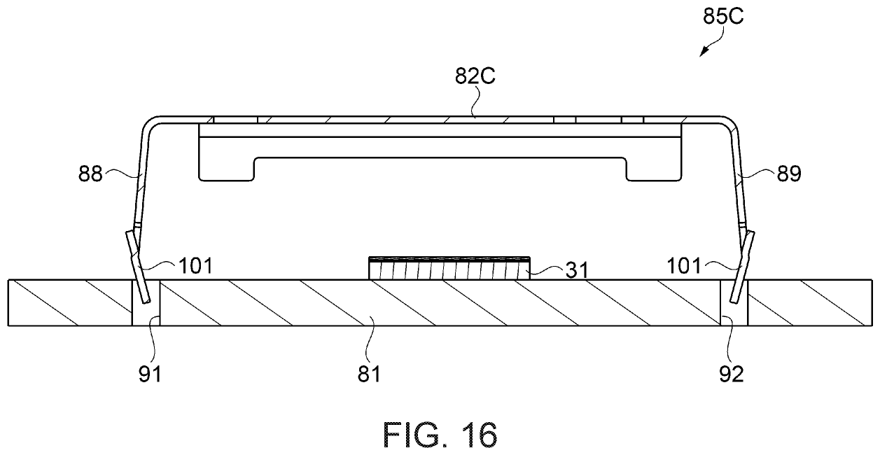

As shown in FIG. 15, the introduction portion 101 of the first leg section 88 and the introduction portion 101 of the second leg section 89 are bent inward. From another viewpoint, the introduction portion 101 of the first leg section 88 and the introduction portion 101 of the second leg section 89 are inclined in directions that are line symmetrical to each other. The introduction portion 101 of the first leg section 88 and the introduction portion 101 of the second leg section 89 are bent in directions line symmetrical to each other. The introduction portion 101 of the first leg section 88 is formed by bending the distal end portion of the first leg section 88, which is formed of a sheet metal. The introduction portion 101 of the second leg section 89 is formed by bending a distal end portion of the second leg section 89, which is formed of a sheet metal. As shown in FIG. 16, since the introduction portions 101 are formed in the shield 82C, the first leg section 88 is easily introduced into the first through hole 91, and the second leg section 89 is easily introduced into the second through hole 92. Further, in the shield 82C, as shown in FIG. 14, the introduction portion 101 has a tip end section 102. The tip end section 102 is formed at the distal end portion of the introduction portion 101, which is at the opposite side from the main body section 87 side. The tip end section 102 has a width dimension H2 that is smaller than the width dimension H1, which is the width dimension of the first leg section 88 and of the second leg section 89 on the main body section 87 side. In other words, in the shield 82C, the distal end part of the first leg section 88 is formed thinner than the main body section 87 side of the first leg section 88. Similarly, in the shield 82C, the distal end part of the second leg section 89 is formed thinner than the main body section 87 side of the second leg section 89. In the shield 82C having the tip end section 102, the first leg section 88 is more easily introduced into the first through hole 91, and the second leg section 89 is more easily introduced into the second through hole 92. Note that a configuration in which the opening 98 of the shield 82B is applied to shield 82C can also be employed.

What is claimed is:

1. An ultrasonic apparatus comprising:
a circuit substrate on which a ground electrode, which is connected to a ground potential, is formed;
an ultrasonic device that is mounted on a first surface of the circuit substrate; and
a shield that is electrically connected to the ground electrode and that surrounds the ultrasonic device; wherein
the circuit substrate has a through hole that penetrates between the first surface and a second surface, which is at an opposite side from the first surface,
the shield has
a main body section that is disposed on the first surface of the circuit substrate and that surrounds the ultrasonic device and
a leg section that extends from the main body section and that passes through the through hole and protrudes from the second surface, and
a protruding section is provided on a portion of the leg section that protrudes from the second surface and the protruding section protrudes, when the second surface is viewed in plan view, further outward than the through hole.

2. The ultrasonic apparatus according to claim 1, wherein
the shield has a contact section that extends from the main body section and that contacts the first surface and
the ground electrode is located in a region that, when viewing the first surface of the circuit substrate in plan view, overlaps the contact section.

3. The ultrasonic apparatus according to claim 1, wherein
an opening is formed in a region of the main body section that, when viewing the first surface in plan view, overlaps the ultrasonic device.

4. The ultrasonic apparatus according to claim 1, wherein
assuming that the through hole is a first through hole, a second through hole that is different from the first through hole is further formed in the circuit substrate,
the second through hole penetrates between the first surface and the second surface,
the first through hole and the second through hole are located, when viewing the first surface in plan view, on opposite sides of the ultrasonic device from each other,
assuming that the leg section is a first leg section, the shield further includes a second leg section that is different from the first leg section,
the second leg section extends from the main body section, passes through the second through hole, and protrudes from the second surface, and
a protruding section is provided on a portion of the second leg section that protrudes from the second surface and the protruding section protrudes, when the second surface is viewed in plan view, further outward than the second through hole.

5. The ultrasonic apparatus according to claim 4, wherein
each of the first leg section and the second leg section has an introduction portion on an opposite side from the main body section side and
the introduction portion of the first leg section and the introduction portion of the second leg section are inclined in directions that are line symmetrical with each other.

6. The ultrasonic apparatus according to claim 5, wherein
the introduction portion has a tip end section on an opposite side from the main body section side and
a width dimension of the tip end section is smaller than a width dimension of a portion between the introduction portion of the first leg section and the second leg section and the main body section.
